(19) United States
(12) Patent Application Publication
(10) Pub. No.: US 2024/0071837 A1
(43) Pub. Date: Feb. 29, 2024

(54) IC FABRICATION FLOW WITH CONTINUOUS DYNAMIC SAMPLING FOR AUTO-VISUAL INSPECTION

(71) Applicant: TEXAS INSTRUMENTS INCORPORATED, Dallas, TX (US)

(72) Inventors: Bin Liu, Shenyang (CN); Lin Lin, Chengdu (CN); Yu Chen Li, Chengdu (CN); Si Si Xie, Chendgu (CN); Zhi Yun Liu, Chengdu (CN); Bo Jiang, Chengdu (CN)

(21) Appl. No.: 17/897,688

(22) Filed: Aug. 29, 2022

(51) Int. Cl. H01L 21/66

(52) U.S. Cl. CPC H01L 22/10; H01L 22/20

(57) ABSTRACT

A wafer metrology system having a continuous dynamic sampling scheme configured to optimize a sampling rate for AVI of process wafers in an IC fabrication flow based on acceptable quality levels. For a stable process, the process wafers may be sampled at a lower rate without negatively affecting quality control.

### FIELD OF THE DISCLOSURE

Disclosed implementations relate generally to the field of semiconductor fabrication using statistical quality control. More particularly, but not exclusively, the disclosed implementations relate to an IC fabrication flow using continuous dynamic sampling for inspection and measurement.

### BACKGROUND

Within the semiconductor industry, there is a constant demand for integrated circuits (ICs) that exhibit higher performance at a lower cost. In order to design and manufacture high performance ICs cost-effectively, several parameters of the products flowing through a manufacturing process, e.g., process wafers, semiconductor dies, etc., need to be monitored and carefully controlled. For example, film properties, thicknesses, linewidths, and defect levels need to be measured, first to optimize the manufacturing process, and then subsequently to ensure that it is operating under control.

Wafer inspection and metrology tools may be deployed at one or more manufacturing stages so as to ensure that appropriate physical and electrical properties of semiconductor devices under production are maintained. Whereas cost-effective wafer metrology is a necessity in modern semiconductor IC fabrication, inspecting and monitoring wafers is not without associated costs. Example costs may typically include capital outlays for the inspection/metrology equipment as well as manufacturing costs such as, e.g., time spent on inspection itself, which slows down wafer throughput; establishment of separate metrology/inspection stations for performing measurements; processing the measurement data; verifying results and dispositioning wafer lots; and the like.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to a continuous dynamic sampling scheme configured to optimize sampling rates for auto-visual inspection (AVI) of process wafers in an IC fabrication flow based on acceptable quality levels. In some example arrangements, the process wafers may be sampled at a lower rate without negatively affecting quality control, wherein different sampling rates and/or quality thresholds may be established for different processing stages of a fabrication flow.

In one example, a method of fabricating an IC is disclosed. The method may include processing a plurality of semiconductor wafers in a fabrication flow having a sequence of process steps including a targeted process step, wherein the targeted process step adds to or subtracts from a material layer over the semiconductor wafers. The method may include inspecting a first sampled fraction of the plurality of semiconductor wafers for a quality characteristic of the material layer, wherein the first sampled fraction having a first sampling size is based on a first sampling rate that may be determined responsive to a continuous sampling scheme. In one arrangement, the first sampling rate may be obtained as a sampling rate that satisfies a first quality level of the quality characteristic being monitored. In some arrangements, the first quality level may be defined based on a variable quality level corresponding to the targeted process step. Responsive to determining the condition that the inspection identifies one or more defective wafers in the first sampled fraction that do not meet a quality threshold of the quality characteristic, a second sampling rate may be determined or otherwise obtained for sampling a subsequent plurality of semiconductor wafers. In one example implementation, the method may also involve adjusting one or more processing conditions of the targeted process step in response to detecting the one or more defective wafers in the first sampled fraction. The method may also involve processing a semiconductor substrate containing the IC at a partially completed manufacturing stage using the targeted process step after adjusting the processing conditions of the targeted process step or stage.

In another example, an integrated circuit (IC) is disclosed, which comprises a material layer formed over a semiconductor wafer at a targeted process step of a fabrication flow, the semiconductor wafer forming a substrate for the IC. In one arrangement, a material layer may be reworked responsive to determining that an inspection with respect to the material layer identifies the semiconductor wafer as being defective, wherein the semiconductor wafer is sampled for inspection at the targeted process step from a plurality of semiconductor wafers based on a continuous sampling scheme having dynamically variable sampling rates depending on a rejection level corresponding to a quality level associated with the targeted process step.

In another example, a method of fabricating articles of manufacture is disclosed. The method may include processing a plurality of articles in a process flow having a sequence of process steps including a targeted process step. The method may include inspecting a first sampled fraction of the plurality of articles for a quality characteristic associated with the targeted process step, wherein the first sampled fraction having a first sampling size may be obtained as a continuous sample based on a first sampling rate. Responsive to the condition that the inspection identifies one or more defective articles in the first sampled fraction that do not meet a quality threshold of the quality characteristic (e.g., a first quality threshold), a second sampling rate and a second sampling size associated with a second sampling fraction may be obtained or otherwise determined for sampling a subsequent plurality of articles, wherein the second sampling rate is greater than the first sampling rate. The method may further include adjusting one or more processing conditions of the targeted process step in response to detecting the one or more defective articles. In some arrangements, the method may also include processing the one or more defective articles using the targeted process step after adjusting the processing conditions of the targeted process step.

### BRIEF DESCRIPTION OF THE DRAWINGS

Implementations of the present disclosure are illustrated by way of example, and not by way of limitation, in the Figures of the accompanying drawings. It should be noted that different references to “an” or “one” implementation in this disclosure are not necessarily to the same implementation, and such references may mean at least one. Further, when a particular feature, structure, or characteristic is described in connection with an implementation, it is submitted that it is within the knowledge of one skilled in the art to effect such feature, structure, or characteristic in connection with other implementations whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIG. 1 depicts a representative wafer auto-visual inspection (AVI) system that may be deployed in association with one or more process stages of a wafer fabrication flow according to some examples of the present disclosure;

FIG. 2 is a flowchart of a representative method involving a continuous sampling scheme (CSS) in a wafer fabrication flow according to some examples of the present disclosure;

FIGS. 3A and 3B depict representative quality level and rejection level charts that may be employed in a CSS implementation according to some examples of the present patent disclosure;

FIGS. 4A-4C are flowcharts of representative methods relating to IC fabrication according to some examples of the present disclosure; and

FIG. 5 is a flowchart of a generalized manufacturing flow employing a CSS implementation for AVI according to an example of the present disclosure.

### DETAILED DESCRIPTION

Examples of the disclosure are described with reference to the attached Figures wherein like reference numerals are generally utilized to refer to like elements. The Figures are not drawn to scale and they are provided merely to illustrate examples. Numerous specific details, relationships, and methods are set forth below to provide an understanding of one or more examples. However, it should be understood that some examples may be practiced without such specific details. In other instances, well-known subsystems, components, structures and techniques have not been shown in detail in order not to obscure the understanding of the examples. Accordingly, it will be appreciated by one skilled in the art that the examples of the present disclosure may be practiced without such specific components, structures or subsystems, etc.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. “Directly connected” may be used to convey that two or more physical features touch, or share an interface between each other. Further, in one or more examples set forth herein, generally speaking, an element, component or module may be configured to perform a function if the element may be programmed for performing or otherwise structurally arranged to perform that function.

Without limitation, examples relating to dynamic sampling of units, products, or more generally, articles of manufacture, for auto-visual inspection will be set forth below in the context of semiconductor wafer fabrication.

Depending on implementation, a semiconductor manufacturing process may comprise a fabrication flow involving one or more thin-film and/or thick-film processing/deposition stages, one or more photolithography stages, diffusion/implant stages, etching stages, chemical-mechanical polishing (CMP) stages, metallization stages, bumping and wire-bonding stages, etc., among others, wherein a plurality of semiconductor wafers may be processed on a wafer-by wafer basis, on a lot-by-lot basis, or in a batch mode involving a number of wafer lots or process runs. At an example process stage, a material layer of the semiconductor wafer may be processed so as to alter one or more physical and/or electrical characteristics of the material layer. In some examples, a process stage may add to or subtract from a material layer, e.g., deposition of conductive layers, nonconductive or dielectric layers, etching or polishing of layers, and the like. In an example arrangement, one or more process steps or stages may be selected, monitored, or otherwise targeted for one or more inspection operations, e.g., automatic or manual visual inspection involving appropriate instrumentation, for a variety of purposes, including but not limited to defect detection, quality control and assurance, specification compliance, and the like. Depending on implementation, one or more images relating to a material layer or at least a portion of a semiconductor process wafer may be inspected according to an inspection plan configured to determine, identify or otherwise select one or more die locations of a wafer or a subset of wafers of a wafer lot selected for inspection according to a customizable sampling scheme having dynamically adjustable sampling rates as will be set forth further below in detail.

In some arrangements, one or more statistical process control (SPC) or statistical quality control (SQC) methodologies may be deployed in a fabrication facility in order to monitor and control a process flow at various stages. In some arrangements, example SPC/SQC methodologies may be deployed at a targeted process stage considered to be a critical process stage in order to help ensure that the targeted process stage is operating efficiently and within control, whereby more conforming products with less waste (e.g., rework, scrap or other disposition) may be reliably produced. For example, process wafers, wafer lots, and/or process runs may be monitored and/or inspected to confirm that applicable control limits and/or specification thresholds are satisfied with respect to one or more parameters and/or variables relevant to the material layer(s) being processed at the targeted process stage. In some arrangements, example SPC/SQC methodologies may include generating run charts, control charts, etc., as well as performing process capability analyses and/or conducting statistically designed experiments, and the like, in order to help meet quality control and assurance goals.

Although various processes may be controlled and monitored by deploying suitable instrumentation and sampling process wafers for in situ or inline measurements and inspection, it should be appreciated that fabrication flows having a large number of process stages as well as deploying technologies with ever-expanding number of dies per wafer can generate enormous amounts of data even in implementations where the processes are considered to be stable and/or in control. Such situations may lead to inefficiencies in terms of overutilization of measurement and inspection resources because excessive data is generated regardless of the stability of the process and/or whether applicable quality control and assurance objectives are being met. As inspection costs are directly correlated to sampling frequencies, unnecessary data generation and processing e.g., due to oversampling, can result in consuming precious computational resources as well as manpower resources, thereby adversely impacting overall cycle times and the productivity of a fabrication flow.

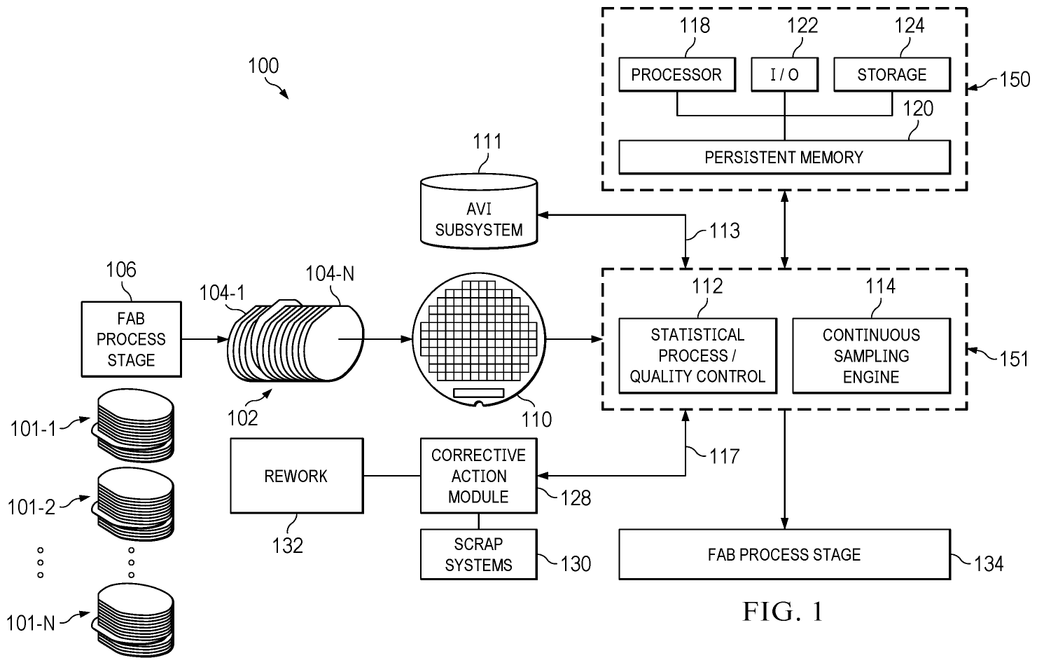

Referring to the drawings, FIG. 1 depicts a representative wafer metrology system 100 that may be deployed in association with one or more process stages of a wafer fabrication flow, wherein a dynamic sampling scheme may be executed according to some examples of the present disclosure in order to reduce and/or optimize inspection operations with respect to applicable metrological sampling units (MSUs), e.g., one or more process wafers or one or more process runs (i.e., a wafer lot), that may be processed and continuously sampled at a targeted process stage of the fabrication flow. As will be seen in further detail below, examples of the disclosure may be configured to provide customized sampling rates according to defined quality levels, e.g., Acceptable Quality Levels (AQLs), Average Outgoing Quality Limits (AOQLs), etc., wherein the sampling rates may be automatically adjusted depending on the results of inspection of continuous samples in view of applicable rejection thresholds. Further, in some additional and/or alternative arrangements, various quality levels, rejection levels and sampling rates may be configured on a stage by stage basis depending on the criticality of the process stages in an example fabrication flow, types of measurement, inspection and defect detection parameters being considered (collectively referred to as “quality parameters” or “quality characteristics”), and the like.

By way of illustration, a generalized targeted process stage or step 106 is exemplified in FIG. 1 that may represent any front-end-of-line (FEOL) stage or a back-end-of-line (BEOL) stage of a fabrication flow, where a plurality of wafers may be batch-processed, e.g., in one or more wafer lots or process runs 101-1 to 101-N. A current wafer lot or MSU 102 comprising semiconductor process wafers 104-1 to 104-N (also referred to as semiconductor wafers, process wafers, or simply wafers) may be selected for measurement or inspection (i.e., sampled) by a suitable AVI station or subsystem 111 responsive to a sampling rate according to a continuous sampling scheme executed by a decision engine or module 151 implemented in any known or heretofore unknown hardware/software/firmware architectures. In some arrangements, the decision engine 151 may be integrated with the AVI station 111. In some arrangements, the decision engine 151 may be deployed as a standalone apparatus. In some arrangements, the decision engine 151 may include a process/quality control module 112 configured to generate, maintain and store various run charts, control charts, process capability indices and distributions, AQL/AOQL databases as well as measurement history data relative to one or more quality parameters that may be measured, detected, inspected or otherwise obtained by the AVI station 111. In some arrangements, the AVI station 111 may include appropriate image processing capabilities as part of a fully automated wafer inspection system that can be configured to analyze images captured at one or more targeted process stages of a fabrication process with little or no human operator intervention. In some arrangements, example AVI station 111 may be implemented as one or more image capturing devices, scanning electron microscopy (SEM) equipment, atomic force microscopy (AFM) equipment, and the like. In some arrangements, example AVI station 111 may be configured to operate in conjunction with additional systems including, without limitation, machine learning (ML) or deep learning (DL) systems based on neural networks, artificial intelligence (AI)-based expert systems, pattern recognition systems, Big Data analytics systems, etc., as well as a variety of databases including historical wafer image databases, defect signature databases, and the like. In some arrangements, depending on the process stage involved, example AVI station 111 may be configured to perform various types of inspection operations including, e.g., patterned wafer inspections, non-patterned wafer inspections, etc., with respect to the quality characteristics germane to the targeted process stage, e.g., photolithography inspections, diffusion and well region inspections, deposition/etching/CMP inspections, interconnection and metallization inspections, bumping/bonding process inspections including under bump metallurgy (UBM) inspections, etc. Further, depending on implementation and the process stage involved, example AVI station 111 may be configured to inspect or detect various quality characteristics such as, e.g., non-uniformities in photo exposures, resist lifting/peeling, solvent drips, blobs, residues, striations, hot spots, pits and scratches, under-etch profiles, resist bubbles, field tilts, metal shorts, micro and macro particles, etc. In still further arrangements involving measurement operations, an example AVI station 111 may be associated with suitable metrological equipment configured to conduct measurements with respect to, inter alia, one or more critical dimension (CD) parameters, overlay alignment parameters, layer thickness parameters, layer planarization parameters, etch profile parameters, as well as suitable electrical parameters such as, e.g., sheet resistance, etc., which may depend on the material layer(s) of the wafers processed at a targeted process stage. By way of illustration, a semiconductor process wafer 110 is exemplified as a wafer under inspection for purposes of some representative arrangements herein.

A continuous sampling engine or module 114 associated with the process control module 112 may be configured to execute a continuous sampling process for generating appropriate control signals 113 to the AVI station 111 in order to dynamically adjust a sampling rate used for sampling a flow of wafers, wafer lots or runs processed through a targeted step, e.g., stage 106, based on applicable AQL/AOQL data established for the flow. For purposes herein, an Acceptable Quality Level or AQL is a statistical parameter reflecting of the maximum acceptable number of defective units in a particular sample size. Average Outgoing Quality Limit (AOQL) is the maximum average outgoing quality (AOQ) for a given acceptance sampling plan for all levels of lot quality given that non-conforming lots are subjected to 100% inspection with replacement of non-conforming units with confirming units. Where lots contain low levels of non-conforming units, the probability of rejection is low and the AOQ (e.g., the proportion of non-conforming units in an outgoing stream) is low. As the level of non-conforming units increases, the AOQ increases. If the level of non-conforming units increases further, the probability of a lot being accepted declines, possibly resulting in an increasing number of lots rejected and subjected to increased inspection. As the level of non-conforming units reaches a high enough point, virtually all lots will be rejected, leading to 100% inspection. In such cases, the AOQ value approaches 0% (because all non-conforming units have been identified and replaced). In general, at any given level of incoming quality [p]>0 in a process flow, the AOQL value is less than the corresponding AQL. Depending on the type of defects and risk control, a manufacturing entity may deploy a range of AQL values, e.g., 0.1% for critical defects, 2.5% for major defects, and 4.0% for minor defects, although other ranges may be used in some arrangements. In some example arrangements herein, AQL values of 0.1% and 0.65% may be deployed at different targeted process stages depending on implementation.

A continuous sample having a size [n] is a sampled population of n successive units, wherein an incoming product flow is sampled at a particular sampling rate or frequency. For example, a continuous sample of 10 at a sampling rate of 50% (i.e., every other unit is sampled from a population) denotes a sample of 10 successive units obtained when every other unit is sampled from the population. In other words, an incoming population of at least 20 units is needed to obtain a continuous sample of 10 units at the 50% rate. As will be seen below, continuous samples of different sizes may be obtained in a sequential manner from a product flow using applicable AQL/AOQL values, wherein the continuous samples may be inspected for defects (e.g., determined as non-conforming according to suitable SPC charts established for the relevant quality characteristics) for a given sampling frequency. Depending on the observed defects compared against the rejection levels associated with a combination of the AQL/AOQL and sampling frequency data, a sampling frequency may be dynamically adjusted, e.g., increased or reduced, to optimize the sampling scheme such that it can be assured that a minimum outgoing quality of production is met at a minimum sampling cost in a fabrication flow.

In one implementation, a measurement/inspection plan deployed in a sampling scheme may be based on different granularity levels as well as aggregation levels of the data collected by the AVI station 111, which in turn may depend on how a current MSU is deployed for measurement. Where an MSU comprises a plurality of semiconductor wafers, e.g., MSU 102, an inspection plan may be configured to determine how many semiconductor wafers are selected from the current MSU 102 (e.g., a subset thereof) as well as how many die locations per each selected process wafer are selected for measurement/inspection. Data relating to a measured/inspected parameter may be aggregated and/or averaged over the entire MSU for plotting on a control chart that tracks the data on a lot-by-lot basis in some implementations. On the other hand, if an MSU comprises a single semiconductor wafer, an example measurement/inspection plan may be based in selecting and identifying a subset of die locations of the sampled semiconductor wafer, wherein the measured/inspected parameter may be plotted on a wafer-by-wafer basis.

As previously noted, the AVI station 111 may be associated with metrological equipment in some arrangements, wherein any measured data may also be used in dynamically varying sampling frequencies used in a continuous sampling scheme deployed at a targeted process stage. Further, multiple quality parameters may be sampled for inspection and/or measurement at a targeted process stage in some implementations. In such arrangements where multiple quality parameters are involved, an example implementation may involve different sampling schemes configured as part of the decision engine 151. Moreover, an example decision engine 151 may be configured to control sampling schemes for more than one targeted process stage. Accordingly, the AVI station 111 and associated metrological equipment, if any, may comprise a variety of measurement tools and inspection systems that may be deployed in a semiconductor fabrication facility in various configurations (e.g., distributed vs. centralized environments) for measuring/inspecting myriad physical, chemical, electrical, mechanical and kinetic properties or characteristics of material layers and other structures formed in or over appropriate semiconductor substrates. In some arrangements, the AVI station 111 and decision engine 151 may be integrated as an inline or in situ process control tooling system, wherein a computing platform 150, e.g., a workstation or a server, having one or more processors 118 coupled to a persistent memory 120 containing machine-executable code or program instructions, may be configured to generate appropriate control signals 113 to dynamically adjust the sampling frequencies for sampling the MSUs of a production flow. Appropriate input/output (I/O) modules 122 and one or more storage units 124 may be provided as part of the computing platform 150 depending on implementation. In some arrangements, where the inspections/measurements with respect to a sampled MSU do not satisfy applicable control limits and/or specification thresholds, appropriate corrective actions may be executed by a module 128 responsive to suitable control signals 117, which may involve identifying the wafers or lots for scrapping or reworking as respectively indicated by blocks 130 and 132, depending on fabrication flow management strategy including cost-benefit considerations as to wafer scrap and reworking guidelines as well as the institutional knowledge and domain expertise relating to the targeted process stage. MSUs that are not sampled as well as the sampled MSUs and any reworked MSUs that are within applicable controls and specifications may proceed to a next process stage 134 of the fabrication flow for further processing.

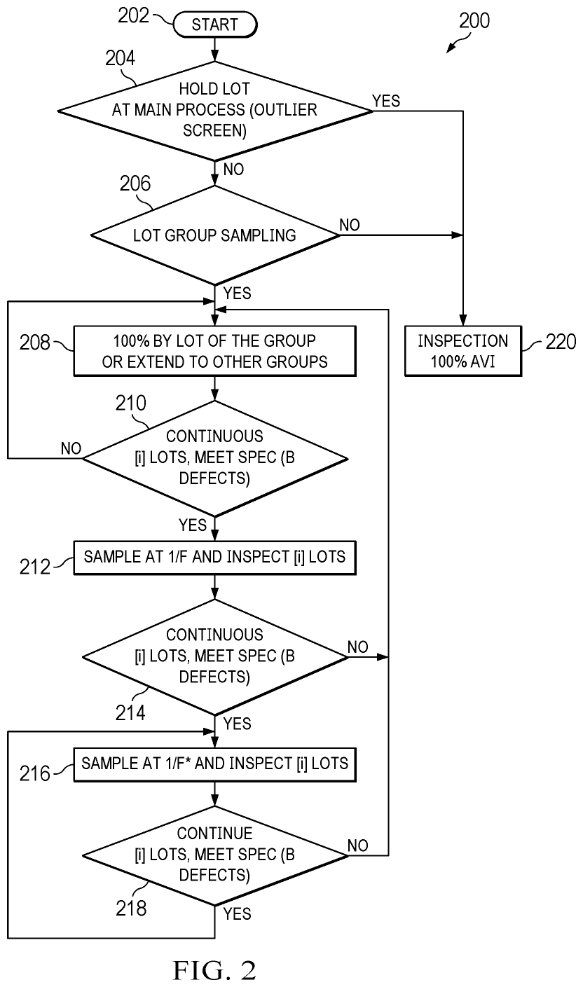

FIG. 2 is a flowchart of a representative method involving a continuous sampling scheme (CSS) in a wafer fabrication flow according to some examples of the present disclosure. In one example arrangement, example method 200 may involve an initial stage 202 wherein various pieces of historical data germane to the quality parameters associated with a plurality of process stages may be measured and plotted with respect to applicable sampling units (e.g., dies, wafers, lots, process runs, etc.), whereby control charts, run charts, etc., having suitable specification thresholds and control limits may be established. Further, applicable AQL/AOQL databases and rejection level databases corresponding to different sampling rates may be established or otherwise obtained from a process flow engineering domain having relevant knowledge or expertise pertaining to a process being managed. In one example implementation, a production flow of wafer lots may be segregated into a hold flow designated for special disposition and a sampled inspection flow designated for further processing including continuous sampling, as set forth at block 204. Such segregation may be beneficial in certain production environments with respect to reducing any confounding abnormalities, outliers or artifacts introduced because of the hold flow lots, which may have a higher potential risk for defects, etc. or otherwise be afflicted with unknown defect modalities. Depending on implementation, some examples of hold flow lots may include one or more exclusions, e.g., special work requests including engineering work lots, hand carry lots (e.g., customer demonstration or demo lots with high priority samples, tool interdiction and monitoring system lots designated for special process control reasons, preventive maintenance lots, pilot lots introducing new mask layers or reticles, or other equipment, etc. In one arrangement, hold flow lots may be subjected to 100% inspection, as indicated by block 220.

With respect to sampled inspection flows, example method 200 may involve categorizing the wafer lots into different groups based on technology, substrate material type, linewidths or CDs, and the like, depending on implementation. Whereas some groups or categories of production flow wafer lots may be amenable to continuous sampling, other groups may be designated otherwise, as set forth at block 206. If a sampled flow belongs to a category not designated for continuous sampling, such a flow may be inspected at a 100% sampling rate (block 220). In some example implementations, categorization of wafer lots with respect to continuous sampling may be changed dynamically, e.g., extending the sampling scheme to other categories. In one arrangement, example method 200 may involve commencing inspection at a 100% sampling rate consecutively until a designated number of MSUs, e.g., [i] successive MSUs, are found clear of defects or within an acceptable limit, e.g., based on applicable SPC charts and AQL/AOQL databases, as set forth at blocks 208, 210. In one arrangement, the initial sampling size [i] for 100% inspection may be defined, determined or otherwise obtained from process engineering based on empirical and/or historical data analysis. If there is a continuous sample [i] at 100% inspection that exhibits a quality level in conformance within the applicable quality characteristics specifications, subsequent MSUs may be sampled at a reduced sampling rate, e.g., a first sampling rate [1/f₁], that is less than 100%, to obtain a continuous sample of suitable size [i] for inspection (block 212). In some examples, the continuous sample size [i] at block 212 may be different than the continuous sample size [i] of block 210 that is obtained using 100% sampling. In example some arrangements, [1/f₁] may be ⅘, ¾, ½, ⅓, ¼, ⅕, etc., depending on implementation.

In one arrangement, if the continuous sample [i] obtained at block 212 based on the [1/f₁] sampling rate does not yield an acceptable quality level (e.g., observed defects or rejections are more than a designated threshold), method 200 reverts to 100% sampling/inspection, as indicated at block 214, which may continue until a next continuous sample of size [i] exhibiting the requisite quality level conformance is found. On the other hand, if the continuous sample [i] obtained at block 212 based on the [1/f₁] sampling rate yields the requisite quality level, the sampling frequency may be reduced to a second sampling rate, e.g., [1/f₂] or [1/f*], where [1/f₂]<[1/f₁], for sampling the subsequent flow of MSUs in order to obtain a continuous sample of size [i] for inspection (block 216). In one arrangement, the reduced sampling rate [1/f₂] may be ⅘, ¾, ½, ⅓, ¼, ⅕, etc., depending on implementation. In some examples, the continuous sample size [i] of block 216 may be different than the continuous sample sizes obtained previously. If the inspection of the continuous sample size of [i] obtained at block 216 yields the requisite quality level conformance, method 200 may continue to sample at this rate for further inspection operations in an iterative manner (block 218). Otherwise, method 200 may revert to a 100% sampling regime set forth at block 208. In some further examples, additional fractional sampling rates may be implemented until a lowest sampling rate that affords the requisite quality level is reached.

It will be appreciated that the foregoing CSS arrangement may be implemented at different process stages having different quality requirements in a configurable manner, wherein variable sampling rates may be optimized for different process stages and material layers. As such, the sampling rates may be defined based on AQL/AOQL databases that encompass different production risk assessments, customer acceptance levels, etc., in light of inherent process flow variations that may occur over time and at different locations. Further, as a process exhibits out-of-specification (OOS) and/or out-of-control (OOC) behavior, thereby causing higher rejection rates, for example, a representative arrangement of the foregoing process may be advantageously configured to tighten the sampling rate, e.g., increasing the sampling rate wherein the MSUs are inspected more frequently.

In some additional and/or alternative arrangements, where control limits are used in an inspection dispositioning process, OOC conditions may be used as an early warning signal in an example implementation. In general, control limits are tighter than specification thresholds established for a monitored quality parameter, although either of them may be configured as a suitable quality threshold that may be used in determining whether an MSU fails inspection with respect to the monitored quality parameter. In some arrangements, tighter OOC limits may be used for executing a variety of prophylactic/corrective actions including, e.g., advancing a current process run or MSU that fails to meet the control limits but satisfies the specification thresholds. In such a scenario, the current MSU may be appropriately flagged for downstream inspection and dispositioning.

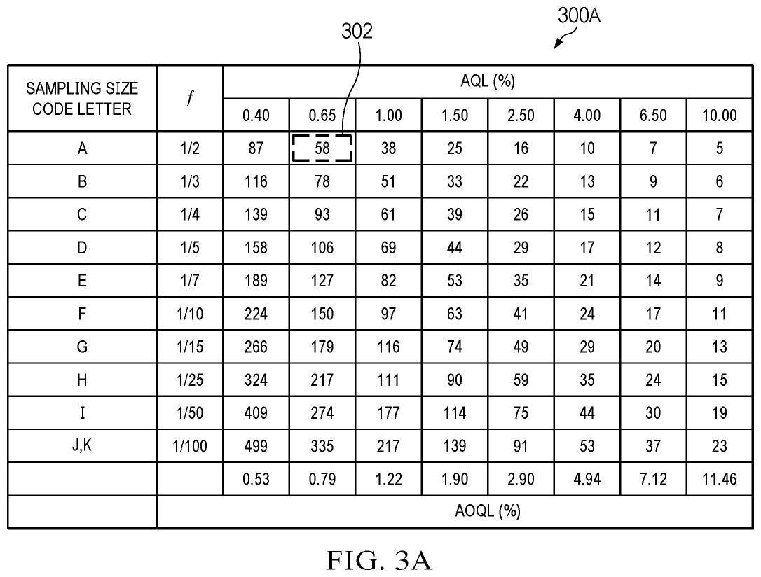

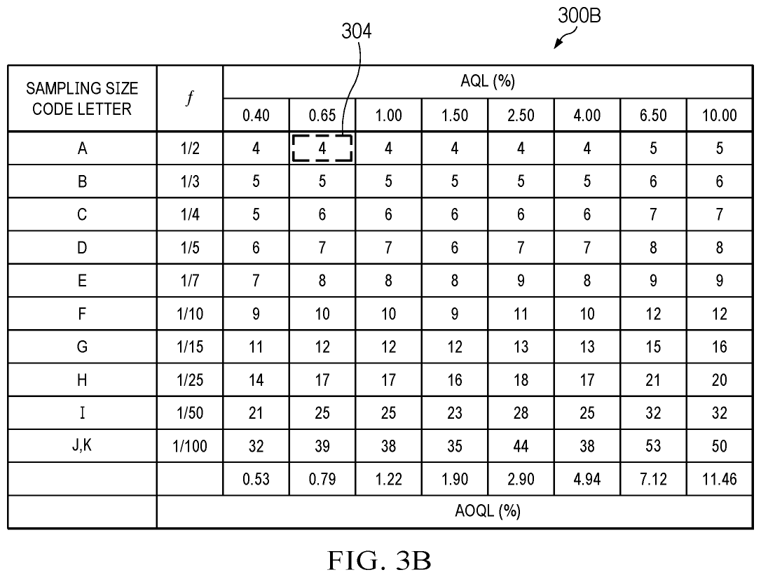

FIGS. 3A and 3B depict example sample size databases and rejection level databases for different quality levels that may be employed according to some implementations of the present patent disclosure. In particular, a sampling size database 300A of FIG. 3A depicts a relationship between various sampling sizes [i] and AQL/AOQL percentage values (e.g., quality levels) for a plurality of sampling rates [1/f], wherein different sampling rates may be designated using alphabetical letter codes in one example implementation. In similar fashion, a rejection level database 300B of FIG. 3B depicts a relationship between rejection levels [r] and AQL/AOQL percentage values for the [1/f] sampling rates and corresponding letter codes in one example implementation. By way of illustration, for a sampling rate plan A, the sampling rate is ½; for a sampling rate plan B, the sampling rate is ⅓, and so on. For a given AQL level and sampling rate plan combination, a sampling size [i] and a rejection level [r] may be obtained by interrogating respective databases 300A and 300B, wherein f refers to a sampling rate ranging from 0% to 100% depending on implementation. As noted previously, databases 300A, 300B or similar constructs may be established by process/quality engineering based on risk assessment and quality control in some arrangements. In one example, for a combination of the sampling rate plan A and AQL of 0.65%, a sampling size [i] of 58 is obtained from the database 300A, as exemplified by reference number 302. Accordingly, a continuous sample of 58 units sampled from an incoming flow at 50% rate (i.e., every other unit is sampled) may undergo inspection at a particular targeted process stage. With respect to the database 300B, a rejection level [r] of 4 may be obtained for the same combination of the sampling rate plan A and AQL of 0.65%, as exemplified by reference number 304. According to an example implementation, the [r] value of 4 corresponding to a continuous sample size [i] of 58 indicates that up to a maximum number of four units having defects may be allowed for the continuous sample comprising 58 units in order for that continuous sample to be deemed acceptable. For purposes herein, a defective unit is a sampled unit that exhibits a defect after inspection, wherein a defect may be broadly defined as a quality parameter that is measured to be non-conforming, e.g., OOS and/or OOC measurements, according to applicable SPC charts corresponding to the quality parameter. Where MSUs may comprise wafers or wafer lots, the defects may be defined in reference to averaged quality parametric values that may be plotted on a wafer-by-wafer basis or a lot-by-lot basis, depending on a measurement plan.

By way of an illustrative example, a CSS implementation may commence with 100% inspection at a particular process stage, with an initial continuous sampling size set at 20 lots. When a continuous sample of 20 lots having an acceptable level of quality is determined, observed or otherwise obtained, the sampling rate may be adjusted to 50% (i.e., every other lot is sampled), with a continuous sampling size set at 30 lots. When a continuous sample of 30 lots exhibiting an acceptable quality is obtained, the sampling rate may be adjusted to ⅓, i.e., every third lot is sampled for inspection.

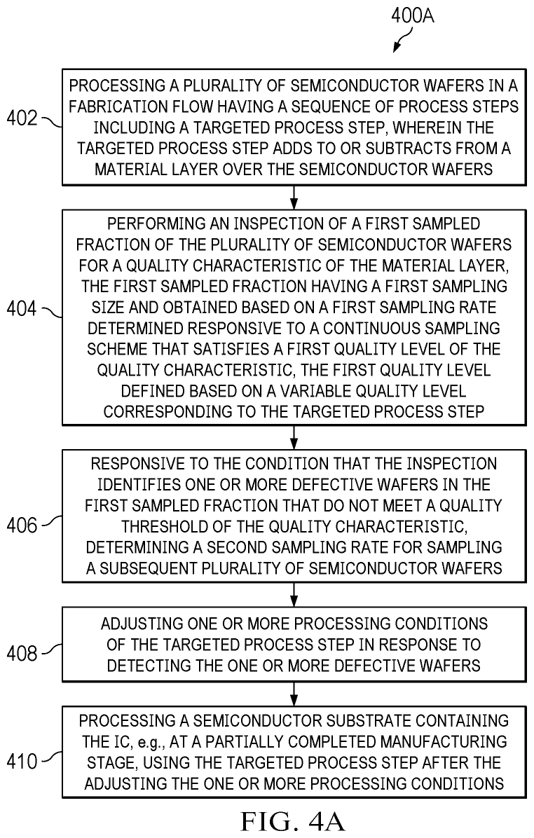

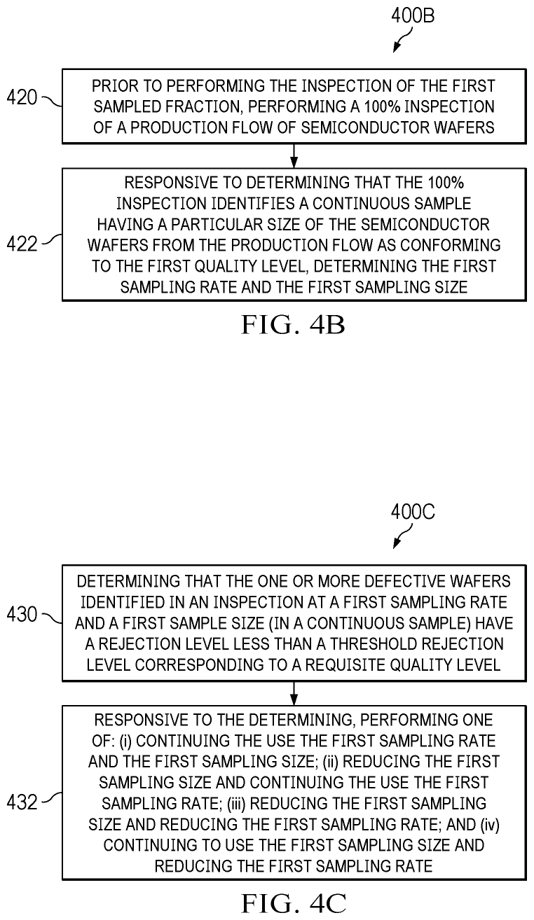

FIGS. 4A-4C are flowcharts of representative methods relating to IC fabrication according to some examples of the present disclosure, which may be combined in some arrangements depending on implementation. Example method 400A may commence with processing a plurality of semiconductor wafers in a fabrication flow having a sequence of process steps including a targeted process step, wherein the targeted process step adds to or subtracts from a material layer over the semiconductor wafers (block 402). At block 404, an inspection may be performed of a first sampled fraction of the plurality of semiconductor wafers for a quality characteristic of the material layer, wherein the first sampled fraction having a first sampling size is obtained based on a first sampling rate that may be determined responsive to a continuous sampling scheme. In one arrangement, the first sampling rate may be obtained as a sampling rate that satisfies a first quality level of the quality characteristic being monitored. In some arrangements, the first quality level may be defined based on a variable quality level corresponding to the targeted process step. For example, a quality level corresponding to a photolithography stage may be different from a quality level corresponding to an etch stage, etc. Responsive to determining the condition that the inspection identifies one or more defective wafers in the first sampled fraction that do not meet a quality threshold of the quality characteristic, a second sampling rate may be determined or otherwise obtained for sampling a subsequent plurality of semiconductor wafers, as set forth at block 406. In one example implementation, method 400A may also involve adjusting one or more processing conditions of the targeted process step in response to detecting the one or more defective wafers in the first sampled fraction (block 408). Method 400A may also involve processing a semiconductor substrate containing the IC at a partially completed manufacturing stage using the targeted process step after adjusting the processing conditions of the targeted process step or stage (block 410). In some example implementations, the semiconductor substrate containing the IC may be a sampled wafer designated for reworking upon identifying that the sampled wafer is defective (e.g., responsive to determining that the monitored quality characteristic is non-conforming based on the applicable SPC charts).

In one implementation, an example method 400B may comprise, prior to performing the inspection of a first sampled fraction, performing a 100% inspection of a production flow of semiconductor wafers (block 420). Responsive to determining that the 100% inspection identifies a particular size of a continuous sample of the semiconductor wafers from the production flow as conforming to a required quality level (e.g., a first quality level), a first sampling rate and a first sampling size may be determined for performing continuous sampling of subsequent wafers of the production flow (block 422).

In one implementation, an example method 400C may comprise determining that one or more defective wafers identified in an inspection pursuant to a first sampling rate and a first sampling size have a rejection level less than a threshold rejection level corresponding to a required quality level (block 430). Responsive to the determining, example method 400C may involve one of: (i) continuing to use the first sampling rate and the first sampling size; (ii) reducing the first sampling size and continuing to use the first sampling rate; (iii) reducing the first sampling size and reducing the first sampling rate; and (iv) continuing to use the first sampling size and reducing the first sampling rate for subsequent sampling operations in a CSS implementation.

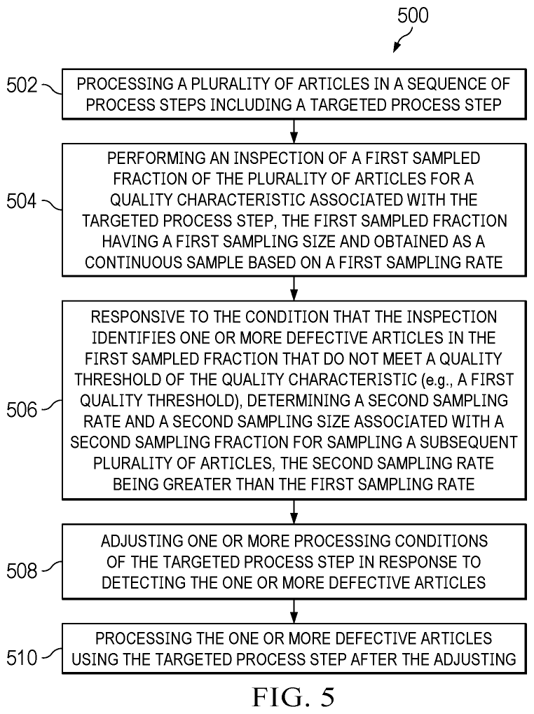

FIG. 5 is a flowchart of a generalized manufacturing flow employing a CSS implementation for AVI according to an example of the present disclosure. For purposes herein, “articles” may be produced by any manufacture from raw or prepared materials, wherein the materials are given new forms, qualities, properties, or combinations, in any type of industry. Depending on implementation, articles may be produced in a variety of modes, e.g., batch production, continuous production, flow production, etc., wherein a suitable MSU may comprise a single article of manufacture or a group of articles of manufacture. Example method 500 may include processing a plurality of articles in a process flow having a sequence of process steps including a targeted process step (block 502). At block 504, an inspection may be performed of a first sampled fraction of the plurality of articles for a quality characteristic associated with the targeted process step, wherein the first sampled fraction having a first sampling size may be obtained as a continuous sample based on a first sampling rate. Responsive to the condition that the inspection identifies one or more defective articles in the first sampled fraction that do not meet a quality threshold of the quality characteristic, a second sampling rate and a second sampling size associated with a second sampling fraction may be obtained or otherwise determined for sampling a subsequent plurality of articles, wherein the second sampling rate is greater than the first sampling rate (block 506). Example method 500 may further include adjusting one or more processing conditions of the targeted process step in response to detecting the one or more defective articles, as set forth at block 508. In some arrangements, example method 500 may also include processing the one or more defective articles using the targeted process step after adjusting the processing conditions of the targeted process step as set forth at block 510.

Various disclosed methods and systems of the present disclosure may be beneficially applied to any manufacturing process so as to dynamically adjust the sampling rate for measurement depending on how the process is behaving, thereby help mitigate or reduce oversampling of the product flow without sacrificing applicable quality control protocols and requirements. Further, examples set forth herein may be implemented in a computationally efficient manner, leading to optimal utilization of hardware/software resources as well as human resources. While such example arrangements may be expected to provide various tangible improvements in the management of a process flow, no particular result is a requirement unless explicitly recited in a particular claim.

One or more examples of the present disclosure may be implemented using different combinations of software, firmware, and/or hardware. Thus, one or more of the techniques shown in the Figures (e.g., flowcharts) may be implemented using code and data stored and executed on one or more electronic devices or nodes (e.g., a workstation, a network element, etc.). Such electronic devices may store and communicate (internally and/or with other electronic devices over a network) code and data using computer-readable media, such as non-transitory computer-readable storage media (e.g., magnetic disks, optical disks, random access memory, read-only memory, flash memory devices, phase-change memory, etc.), transitory computer-readable transmission media (e.g., electrical, optical, acoustical or other form of propagated signals—such as carrier waves, infrared signals, digital signals), etc. In addition, some network elements or workstations, e.g., configured as servers, may typically include a set of one or more processors coupled to one or more other components, such as one or more storage devices (e.g., non-transitory or persistent machine-readable storage media) as well as storage database(s), user input/output devices (e.g., a keyboard, a touch screen, a pointing device, one or more imaging capturing devices and/or a display, etc.), and network connections for effectuating signaling and/or data transmission. The coupling of the set of processors and other components may be typically through one or more buses and bridges (also termed as bus controllers), arranged in any known (e.g., symmetric/shared multiprocessing) or heretofore unknown architectures. Thus, the storage device or component of a given electronic device or network element may be configured to store program code and/or data for execution on one or more processors of that element, node or electronic device for purposes of implementing one or more techniques of the present disclosure.

At least some examples are described herein with reference to one or more circuit diagrams/schematics, block diagrams and/or flowchart illustrations. It is understood that such diagrams and/or flowchart illustrations, and combinations of blocks in the block diagrams and/or flowchart illustrations, can be implemented by any appropriate circuitry configured to achieve the desired functionalities. Accordingly, some examples of the present disclosure may be embodied in hardware and/or in software (including firmware, resident software, micro-code, etc.) operating in conjunction with suitable processing units or microcontrollers, which may collectively be referred to as “circuitry,” “a module” or variants thereof. An example processing unit or a module may include, by way of illustration, a general purpose processor, a special purpose processor, a conventional processor, a digital signal processor (DSP), an image processing engine or unit, a plurality of microprocessors, one or more microprocessors in association with a DSP core, a controller, a microcontroller, Application Specific Integrated Circuits (ASICs), Field Programmable Gate Array (FPGA) circuits, any other type of integrated circuit (IC), and/or a state machine, as well as programmable system devices (PSDs) employing system-on-chip (SoC) architectures that combine memory functions with programmable logic on a chip that is designed to work with a standard microcontroller. Example memory modules or storage circuitry may include volatile and/or non-volatile memories such as, e.g., random access memory (RAM), electrically erasable/programmable read-only memories (EEPROMs) or UV-EPROMS, one-time programmable (OTP) memories, Flash memories, static RAM (SRAM), etc.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

It should therefore be clearly understood that the order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure.

At least some portions of the foregoing description may include certain directional terminology, which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged mutatis mutandis, depending on the context, implementation, etc. Further, the features of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” All structural and functional equivalents to the elements of the above-described implementations that are known to those of ordinary skill in the art are expressly incorporated herein by reference and are intended to be encompassed by the claims appended below.

What is claimed is:

1. A method of fabricating an integrated circuit (IC), the method comprising:
processing a plurality of semiconductor wafers in a fabrication flow having a sequence of process steps including a targeted process step, wherein the targeted process step adds to or subtracts from a material layer over the semiconductor wafers;
performing an inspection of a first sampled fraction of the plurality of semiconductor wafers for a quality characteristic of the material layer, the first sampled fraction having a first sampling size based on a first sampling rate determined responsive to a continuous sampling scheme that satisfies a first quality level of the quality characteristic, the first quality level defined based on a variable quality level corresponding to the targeted process step;
on the condition that the inspection identifies one or more defective wafers in the first sampled fraction that do not meet a quality threshold of the quality characteristic, determining a second sampling rate for sampling a subsequent plurality of semiconductor wafers;
adjusting one or more processing conditions of the targeted process step in response to detecting the one or more defective wafers; and
processing a semiconductor substrate containing the IC at a partially completed manufacturing stage using the targeted process step after the adjusting.

2. The method as recited in claim 1, wherein the second sampling rate is greater than the first sampling rate.

3. The method as recited in claim 1, further comprising:
prior to performing the inspection of the first sampled fraction, performing a 100% inspection of a production flow of semiconductor wafers; and
responsive to determining that the 100% inspection identifies a particular size of a continuous sample of the semiconductor wafers from the production flow as conforming to the first quality level, determining the first sampling rate and the first sampling size.

4. The method as recited in claim 1, wherein the first sampled fraction comprises a continuous sample of the plurality of semiconductor wafers obtained from sampling the plurality of semiconductor wafers at the first sampling rate.

5. The method as recited in claim 1, further comprising determining a second sampling size associated with a second sampled fraction for sampling from the subsequent plurality of semiconductor wafers.

6. The method as recited in claim 5, wherein the second sampling size is different than the first sampling size.

7. The method as recited in claim 5, wherein the second sampled fraction is obtained as a continuous sample of the subsequent plurality of semiconductor wafers sampled at the second sampling rate.

8. The method as recited in claim 1, wherein the second sampling rate comprises a 100% sampling rate.

9. The method as recited in claim 1, further comprising:
determining that the one or more defective wafers identified in the inspection are less than a threshold rejection level corresponding to the first quality level; and
responsive to the determining, performing one of: (i) continuing to use the first sampling rate and the first sampling size; (ii) reducing the first sampling size and continuing to use the first sampling rate; (iii) reducing the first sampling size and reducing the first sampling rate; and (iv) continuing to use the first sampling size and reducing the first sampling rate.

10. The method as recited in claim 1, further comprising, prior to performing the inspection of the first sampled fraction, segregating a production flow of semiconductor wafers into a hold flow and an inspection flow, wherein wafers in the hold flow are inspected at a 100% inspection rate and wafers in the inspection flow are identified for inspection based on the continuous sampling scheme commencing with the first sampling rate.

11. A method of fabricating articles of manufacture, the method comprising:
processing a plurality of articles in a sequence of process steps including a targeted process step;
performing an inspection of a first sampled fraction of the plurality of articles for a quality characteristic associated with the targeted process step, the first sampled fraction having a first sampling size and obtained as a continuous sample based on a first sampling rate;
on the condition that the inspection identifies one or more defective articles in the first sampled fraction that do not meet a first quality threshold of the quality characteristic, determining a second sampling rate and a second sampling size associated with a second sampling fraction for sampling a subsequent plurality of articles, the second sampling rate being greater than the first sampling rate;
adjusting one or more processing conditions of the targeted process step in response to detecting the one or more defective articles; and
processing the one or more defective articles using the targeted process step after the adjusting.

12. The method as recited in claim 11, further comprising:
prior to performing the inspection of the first sampled fraction, performing a 100% inspection of a production flow of the articles of manufacture; and
responsive to determining that the 100% inspection identifies a particular size of a continuous sample of the articles from the production flow as conforming to the quality threshold, determining the first sampling rate and the first sampling size.

13. The method as recited in claim 11, wherein the second sampling size is different than the first sampling size.

14. The method as recited in claim 11, further wherein the second sampled fraction is obtained as a continuous sample of the subsequent plurality of articles sampled at the second sampling rate.

15. The method as recited in claim 11, wherein the second sampling rate comprises a 100% sampling rate.

16. The method as recited in claim 11, further comprising:
inspecting the second sampled fraction of the subsequent plurality of articles;
determining that the inspection of the second sampled fraction identifies one or more defective articles less than a threshold rejection level corresponding to the first quality threshold; and
responsive to the determining, reverting to use the first sampling rate or the first sampling size for sampling.

17. An integrated circuit (IC), comprising:
a material layer formed over a semiconductor wafer at a targeted process step of a fabrication flow, the semiconductor wafer forming a substrate for the IC; and
the material layer reworked responsive to determining that an inspection with respect to the material layer identifies the semiconductor wafer as being defective, the semiconductor wafer sampled for inspection at the targeted process step from a plurality of semiconductor wafers based on a continuous sampling scheme having dynamically variable sampling rates depending on a rejection level corresponding to a quality level associated with the targeted process step.
